(19) United States
(12) Patent Application Publication
(10) Pub. No.: US 2012/0279559 A1
(43) Pub. Date: Nov. 8, 2012

(54) SOLAR MODULES HAVING A POLYCARBONATE BLEND FILM AS THE REAR FACE FILM

(75) Inventors: Gunther Stollwerck, Krefeld (DE); Ernst-Ulrich Reisner, Moers (DE); Katrin Petzel-Maryniak, Willich (DE); Andreas Seidel, Dormagen (DE)

(73) Assignee: Bayer MaterialScience AG, Leverkusen (DE)

(21) Appl. No.: 13/497,869

(22) PCT Filed: Oct. 1, 2010
(86) PCT No.: PCT/EP2010/064631

§ 371 Date: Jul. 25, 2012

(30) Foreign Application Priority Data
Oct. 6, 2009 (EP) 09012599.8

(51) Int. Cl. H01L 31/048; H01L 31/18

(52) U.S. Cl. 136/251; 438/73; 257/E31.11

(57) ABSTRACT

The present invention relates to solar modules comprising polycarbonate blend films as rear face films for protection against weathering and mechanical damage.

The present invention relates to solar modules comprising polycarbonate blend films as rear face films for protection against weathering and mechanical damage.

The structure of a solar module as a rule comprises a transparent front face sheet of glass or plastic or film of plastic, a transparent hot-melt adhesive layer of ethylene/vinyl acetate (EVA) or thermoplastic polyurethane (TPU), in which the solar cells are embedded, and a usually white rear face composite film of polyvinyl fluoride (PVF) and polyethylene terephthalate (PET). Such composite films are described e.g. in WO-A 90/06849. They comprise a PET core laminated on both sides with a PVF layer. The PET serves as an inexpensive carrier which, however, is not stable to weathering, whereas the PVF layer has the effect of protection against weathering. Such films are currently used on a grand scale, but have the disadvantage that they are costly to produce (extrusion plus lamination) and are comparatively expensive.

Rear face films of polycarbonate with an inorganic oxide layer as a barrier to water vapour are furthermore known from the patent literature (JP-A 2006-324556). A disadvantage of these films, however, is that the oxide layer usually acts simultaneously as a debonding layer, so that after weathering the rear face film no longer adheres to the embedding layer for the solar cells.

JP-A 2005-277187 discloses a solar module which comprises polymer films of the same type on the front and rear face, the rear face film being coloured white. The polymer can be polycarbonate, polyethylene or polyethylene terephthalate. If the solar module has no rigid carrier, such as glass or the like, the solar cells are not adequately protected mechanically against flexing and shattering.

The object of the present invention is therefore to provide a solar module which has good stability to weathering (in particular stability in a damp warm climate) and ensures protection against mechanical damage. The object of the present invention was preferably to provide such a solar module which comprises a rear face film which is easy to produce, i.e. preferably in a single extrusion or coextrusion step, and furthermore has good stability to weathering (in particular resistance in a damp warm climate) and ensures protection against mechanical damage.

This object has been achieved according to the invention in that a film of a polycarbonate blend has been employed as the rear face film for a solar module, the polycarbonate blend containing at least one aromatic polycarbonate and/or aromatic polyester carbonate, at least one rubber-containing graft polymer and optionally at least one rubber-free vinyl monomer-based polymer or copolymer or alternatively optionally at least one aromatic polyester and optionally one or more conventional polymer additives.

The present invention accordingly provides a solar module comprising
at least one transparent glass pane, sheet of plastic or film of plastic on the front face,
at least one single- or multilayer film on the rear face,
one or more solar cells,
at least one layer of at least one transparent plastic, in which the solar cells are embedded, between the transparent glass pane, sheet of plastic or film of plastic and the single- or multilayer rear face film.
   characterized in that the single- or multilayer film on the rear face has at least one layer of a composition comprising at least the following components:
A) 30 to 85 parts by wt., preferably 40 to 80 parts by wt., particularly preferably 40 to 70 parts by wt., based on the sum of components A)+B)+C), of aromatic polycarbonate and/or aromatic polyester carbonate,
B) 7 to 70 parts by wt., preferably 13 to 60 parts by wt., particularly preferably 15 to 30 parts by wt., based on the sum of components A)+B)+C), of at least one rubber-containing graft polymer, in a preferred embodiment based on a diene-free rubber as the graft base, in a particularly preferred embodiment based on an acrylate rubber, silicone rubber or very particularly preferably a silicone/acrylate composite rubber as the graft base,
C) 0 to 60 parts by wt., preferably 0 to 40 parts by wt., particularly preferably 15 to 30 parts by wt., based on the sum of components A)+B)+C), of at least one rubber-free vinyl monomer-based polymer or vinyl monomer-based copolymer or alternatively at least one aromatic polyester,
   the sum of components A to C being standardized to 100 parts by wt., and optionally
D) 0 to 30 parts by wt., preferably 0.01 to 20 parts by wt., particularly preferably 0.1 to 15 parts by wt., based on the sum of components A) +B)+C) of at least one polymer additive.

The solar module according to the invention can be a non-flexible or flexible solar module. Possible sheets of plastic or films of plastic for the front face are preferably those of polycarbonate, polymethyl methacrylate, polyethylene terephthalate or fluorine polymers. Suitable glass panes, sheets of plastic or films of plastic can moreover have further coatings, such as e.g. scratch-resistant coatings etc., on the front face, i.e. the face directed outwards in the solar module. The film of plastic can moreover be a multilayer composite film. Solar modules with a glass pane on the front face are preferred.

The transparent glass pane, sheet of plastic or film of plastic preferably has a thickness of from 0.3 mm to 4 mm.

The layer of at least one transparent plastic in which the solar cells are embedded preferably has hot-melt adhesive properties. Possible plastics which are preferably suitable for this layer are ethylene/vinyl acetate (EVA), thermoplastic polyurethane (TPU), polyvinyl butyral (PVB) or silicone rubber.

Possible solar cells are solar cells of mono- or polycrystalline silicon or thin film solar cells. Preferably, the solar module according to the invention comprises several solar cells.

The solar module according to the invention can furthermore comprise a profile frame. This can be made of metal, preferably of aluminium, or of a preferably weathering-resistant plastic. It serves, for example, to protect the glass pane, sheet of plastic or film of plastic on the front face during transportation, handling and assembling and to fix and stiffen the solar module.

The individual components of the composition for the single- or multilayer film on the rear face of the solar module according to the invention are described in detail in the following.

### Component A)

Aromatic polycarbonates according to component A) which are suitable according to the invention are known from the literature or can be prepared by processes known from the literature (for the preparation of aromatic polycarbonates see, for example, Schnell, “Chemistry and Physics of Polycarbonates”, Interscience Publishers, 1964 and DE-AS 1 495 626, DE-A 2 232 877, DE-A 2 703 376, DE-A 2 714 544, DE-A 3 000 610, DE-A 3 832 396; for the preparation of aromatic polyester carbonates e.g. DE-A 3 077 934).

Aromatic polycarbonates are prepared e.g. by reaction of diphenols with carbonic acid halides, preferably phosgene, and/or with aromatic dicarboxylic acid dihalides, preferably benzenedicarboxylic acid dihalides, by the interfacial process, optionally using chain terminators, for example monophenols, and optionally using branching agents which are trifunctional or more than trifunctional, for example triphenols or tetraphenols. A preparation via a melt polymerization process by reaction of diphenols with, for example, diphenyl carbonate is likewise possible.

Diphenols for the preparation of the aromatic polycarbonates and/or aromatic polyester carbonates are preferably those of the formula (I)

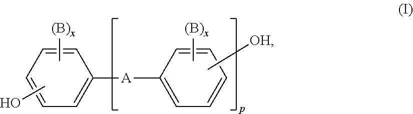

wherein
A is a single bond, C₁ to C₅-alkylene, C₂ to C₅-alkylidene, C₅ to C₆-cycloalkylidene, —O—, —SO—, —CO—, —S—, —SO₂—, C₆ to C₁₂-arylene, on to which further aromatic rings optionally containing hetero atoms can be fused,
   or a radical of the formula (II) or (III)

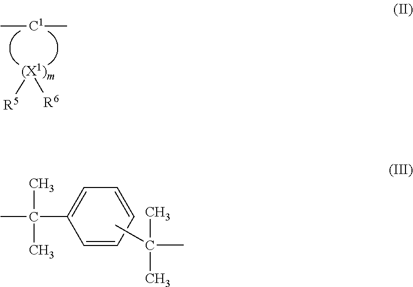

wherein
X¹ represents carbon,
R⁵ and R⁶ can be chosen individually for each X¹ and independently of each other represent hydrogen or C₁ to C₆-alkyl, preferably hydrogen, methyl or ethyl, and
m represents an integer from 4 to 7, preferably 4 or 5, with the proviso that on at least one atom X¹ R⁵ and R⁶ are simultaneously alkyl,
B is in each case C₁ to C₁₂-alkyl, preferably methyl, halogen, preferably chlorine and/or bromine,
x is in each case independently of each other 0, 1 or 2,
p is 1 or 0.

Preferred diphenols are hydroquinone, resorcinol, dihydroxydiphenols, bis-(hydroxyphenyl)-C₁-C₅-alkanes, bis-(hydroxyphenyl)-C₅-C₆-cycloalkanes, bis-(hydroxyphenyl) ethers, bis-(hydroxyphenyl) sulfoxides, bis-(hydroxyphenyl) ketones, bis-(hydroxyphenyl) sulfones and α,α-bis-(hydroxyphenyl)-diisopropylbenzenes and derivatives thereof brominated on the nucleus and/or chlorinated on the nucleus.

Particularly preferred diphenols are 4,4′-dihydroxydiphenyl, 2,2-bis-(4-hydroxyphenyl)-propane (bisphenol-A), 2,4-bis(4-hydroxyphenyl)-2-methylbutane, 1,1-bis-(4-hydroxyphenyl)-cyclohexane, 1,1-bis-(4-hydroxyphenyl)-3,3,5-trimethylcyclohexane, 4,4′-dihydroxydiphenyl sulfide, 4,4′-dihydroxydiphenyl sulfone and di- and tetrabrominated or chlorinated derivatives thereof, such as, for example, 2,2-bis(3-chloro-4-hydroxyphenyl)-propane, 2,2-bis-(3,5-dichloro-4-hydroxyphenyl)-propane or 2,2-bis-(3,5-dibromo-4-hydroxyphenyl)-propane. 2,2-Bis-(4-hydroxyphenyl)-propane (bisphenol A) is particularly preferred.

The diphenols can be employed individually or as any desired mixtures. The diphenols are known from the literature or obtainable by processes known from the literature.

Chain terminators which are suitable for the preparation of the thermoplastic aromatic polycarbonates are, for example, phenol, p-chlorophenol, p-tert-butylphenol or 2,4,6-tribromophenol, but also long-chain alkylphenols, such as 4-[2-(2,4,4-trimethylpentyl)]-phenol, 4-(1,3-tetramethylbutyl)-phenol according to DE-A 2 842 005 or monoalkylphenols or dialkylphenols having a total of 8 to 20 carbon atoms in the alkyl substituents, such as 3,5-di-tert-butylphenol, p-iso-octylphenol, p-tert-octylphenol, p-dodecylphenol and 2-(3,5-dimethylheptyl)-phenol and 4-(3,5-dimethylheptyl)-phenol. The amount of chain terminators to be employed is in general between 0.5 mol % and 10 mol %, based on the sum of the moles (sum of the substance amounts) of the particular diphenols employed.

The thermoplastic aromatic polycarbonates can be branched in a known manner, and in particular preferably by incorporation of from 0.05 to 2.0 mol %, based on the sum of the substance amounts of the diphenols employed, of compounds which are trifunctional or more than trifunctional, for example those having three and more phenolic groups.

Both homopolycarbonates and copolycarbonates are suitable. 1 to 25 wt. %, preferably 2.5 to 25 wt. %, based on the total amount of diphenols to be employed, of polydiorganosiloxanes with hydroxyaryloxy end groups can also be employed for the preparation of copolycarbonates according to the invention according to component A). These are known (U.S. Pat. No. 3,419,634) and can be prepared by processes known from the literature. The preparation of copolycarbonates containing polydiorganosiloxane is described in DE-A 3 334 782.

Preferred polycarbonates are, in addition to bisphenol A homopolycarbonates, copolycarbonates of bisphenol A with up to 15 mol %, based on the sum of the moles of diphenols, of other diphenols mentioned as preferred or particularly preferred, in particular 2,2-bis(3,5-dibromo-4-hydroxyphenyl)-propane.

Aromatic dicarboxylic acid dihalides for the preparation of aromatic polyester carbonates are preferably the diacid dichlorides of isophthalic acid, terephthalic acid, diphenyl ether 4,4′-dicarboxylic acid and of naphthalene-2,6-dicarboxylic acid.

Mixtures of the diacid dichlorides of isophthalic acid and of terephthalic acid in a ratio of between 1:20 and 20:1 are particularly preferred.

A carbonic acid halide, preferably phosgene, is additionally co-used as a bifunctional acid derivative in the preparation of polyester carbonates.

Possible chain terminators for the preparation of the aromatic polyester carbonates are, in addition to the monophenols already mentioned, also chlorocarbonic acid esters thereof and the acid chlorides of aromatic monocarboxylic acids, which can optionally be substituted by C₁ to C₂₂-alkyl groups or by halogen atoms, and aliphatic C₂ to C₂₂-monocarboxylic acid chlorides.

The amount of chain terminators is in each case 0 to 10 mol %, based on the substance amount (moles) of diphenol in the case of the phenolic chain terminators and on the substance amount (moles) of dicarboxylic acid dichloride in the case of monocarboxylic acid chloride chain terminators.

The aromatic polyester carbonates can also contain incorporated aromatic hydroxycarboxylic acids.

The aromatic polyester carbonates can be either linear or branched in a known manner (in this context see DE-A 2 940 024 and DE-A 3 007 934).

Branching agents which can be used are, for example, carboxylic acid chlorides which are trifunctional or more than trifunctional, such as trimesic acid trichloride, cyanuric acid trichloride, 3,3′,4,4′-benzophenone-tetracarboxylic acid tetrachloride, 1,4,5,8-naphthalenetetracarboxylic acid tetrachloride or pyromellitic acid tetrachloride, in amounts of from 0.01 to 1.0 mol % (based on the substance amount of the dicarboxylic acid dichlorides employed), or phenols which are trifunctional or more than trifunctional, such as phloroglucinol, 4,6-dimethyl-2,4,6-tri-(4-hydroxyphenyl)-hept-2-ene, 4,6-dimethyl-2,4,6-tri-(4-hydroxyphenyl)-heptane, 1,3,5-tri-(4-hydroxyphenyl)-benzene, 1,1,1-tri-(4-hydroxyphenyl)-ethane, tri-(4-hydroxyphenyl)-phenylmethane, 2,2-bis[4,4-bis(4-hydroxyphenyl)-cyclohexyl]-propane, 2,4-bis(4-hydroxyphenylisopropyl)-phenol, tetra-(4-hydroxyphenyl)-methane, 2,6-bis(2-hydroxy-5-methylbenzyl)-4-methylphenol, 2-(4-hydroxyphenyl)-2-(2,4-dihydroxyphenyl)-propane, tetra-(4-[4-hydroxyphenyl-isopropyl]-phenoxy)-methane or 1,4-bis[4,4′-dihydroxytriphenyl)-methyl]-benzene, in amounts of from 0.01 to 1.0 mol %, based on the substance amount of the diphenols employed. Phenolic branching agents can be initially introduced with the diphenols, and acid chloride branching agents can be introduced together with the acid dichlorides.

The content of carbonate structural units in the thermoplastic aromatic polyester carbonates can vary as desired. Preferably, the content of carbonate groups is up to 100 mol %, in particular up to 80 mol %, particularly preferably up to 50 mol %, based on the sum of ester groups and carbonate groups. Both the ester and the carbonate content of the aromatic polyester carbonates can be present in the polycondensate in the form of blocks or in random distribution.

The relative solution viscosity (ηᵣₑₗ) of the aromatic polycarbonates and polyester carbonates is preferably in the range of 1.20 to 1.50, preferably from 1.25 to 1.40, particularly preferably from 1.27 to 1.35 (measured on solutions of 0.5 g of polycarbonate or polyester carbonate in 100 ml of methylene chloride solution at 25 ° C.).

### Component B)

Component B) is a graft polymer or a mixture of several graft polymers. Graft polymers which are preferably employed as component B) include one or more graft polymers of
B.1) 5 to 95, preferably 20 to 90, particularly preferably 25 to 50 wt.%, based on the total weight of component B), of at least one vinyl monomer on
B.2) 95 to 5, preferably 80 to 10, particularly preferably 75 to 50 wt.%, based on the total weight of component B), of one or more graft bases with glass transition temperatures of below 10° C., preferably below 0° C., particularly preferably below −20° C.

The glass transition temperatures can be determined by means of dynamic differential thermal analysis (DSC) in accordance with one of the standards DIN EN ISO 11357, DIN 53765 or DIN EN 61006.

The graft base B.2) in general has an average particle size (d₅₀ value) of from 0.05 to 10 μm, preferably 0.07 to 2 μm, particularly preferably 0.1 to 0.6 μm.

The average particle size d₅₀ is the diameter above and below which in each case 50 wt. % of the particles lie. It can be determined by means of ultracentrifuge measurement (W. Scholtan, H. Lange, Kolloid, Z. and Z. Polymere 250 (1972), 782-1796).

Monomers B.1) are mixtures of
B.1.1) 50 to 99, preferably 60 to 80, particularly preferably 70 to 80 wt. %, based on the total weight of component B.1), of vinylaromatics and/or vinylaromatics substituted on the nucleus, such as e.g. styrene, α-methylstyrene, p-methylstyrene, p-chlorostyrene, and/or methacrylic acid (C₁-C₈)-alkyl esters, such as e.g. methyl methacrylate, ethyl methacrylate, and
B.1.2) 1 to 50, preferably 20 to 40, particularly preferably 20 to 30 wt.%, based on B.1), of vinyl cyanides, such as e.g. unsaturated nitriles, such as acrylonitrile and methacrylonitrile), and/or (meth)acrylic acid (C₁-C₈)-alkyl esters, such as e.g. methyl methacrylate, n-butyl acrylate, t-butyl acrylate, and/or derivatives (such as anhydrides and imides) of unsaturated carboxylic acids, such as e.g. maleic anhydride and N-phenyl-maleimide.

Preferred monomers B.1.1) are chosen from at least one of the monomers styrene, α-methylstyrene and methyl methacrylate, and preferred monomers B.1.2) are chosen from at least one of the monomers acrylonitrile, maleic anhydride and methyl methacrylate. Particularly preferred monomer combinations are styrene, as B.1.1), and acrylonitrile, as B.1.2), and as B.1.1) and as B.1.2) in each case methyl methacrylate.

Graft bases B.2) which are suitable for the graft polymers B) are, for example, diene rubbers, EP(D)M rubbers, i.e. those based on ethylene/propylene and optionally diene, and acrylate, polyurethane, silicone, chloroprene and ethylene/vinyl acetate rubbers and silicone/acrylate composite rubbers.

The graft copolymers B) are prepared by free-radical polymerization, e.g. by emulsion, suspension, solution or bulk polymerization, preferably by emulsion polymerization.

Particularly suitable graft polymers B) have a core-shell structure.

The gel content of the graft base B.2) of graft polymers prepared in emulsion polymerization is at least 30 wt. %, preferably at least 40 wt. % (measured in toluene). The gel content of the graft base B.2) is determined at 25° C. in a suitable solvent as the content insoluble in these solvents (M. Hoffmann, H. Krömer, R. Kuhn, Polymeranalytik I and II, Georg Thieme-Verlag, Stuttgart 1977).

Since as is known the grafting monomers are not necessarily grafted completely on to the graft base during the grafting reaction, according to the invention graft polymers B) are also understood as meaning those products which are produced by (co)polymerization of the grafting monomers in the presence of the graft base and are also obtained during the working up. These products can accordingly also contain free, i.e. not bonded chemically to the rubber, (co)polymer of the grafting monomers.

Acrylate rubbers, silicone rubbers or silicone/acrylate composite rubbers are preferably employed as the graft base B.2) in the preparation of the graft polymers B). Silicone/acrylate composite rubbers are particularly preferred.

Suitable acrylate rubbers according to B.2) are preferably polymers of acrylic acid alkyl esters, optionally with up to 40 wt. %, based on B.2), of other polymerizable ethylenically unsaturated monomers. The preferred polymerizable acrylic acid esters include C₁ to C₈-alkyl esters, for example methyl, ethyl, butyl, n-octyl and 2-ethylhexyl esters; haloalkyl esters, preferably halo-C₁-C₈-alkyl esters, such as chloroethyl acrylate, and mixtures of these monomers.

For crosslinking, monomers having more than one polymerizable double bond can be copolymerized. Preferred examples of crosslinking monomers are esters of unsaturated monocarboxylic acids having 3 to 8 C atoms and unsaturated monofunctional alcohols having 3 to 12 C atoms, or of saturated polyols having 2 to 4 OH groups and 2 to 20 C atoms, such as ethylene glycol dimethacrylate, allyl methacrylate; polyunsaturated heterocyclic compounds, such as trivinyl and triallyl cyanurate; polyfunctional vinyl compounds, such as di- and trivinylbenzenes; but also triallyl phosphate and diallyl phthalate. Preferred crosslinking monomers are allyl methacrylate, ethylene glycol dimethacrylate, diallyl phthalate and heterocyclic compounds which contain at least three ethylenically unsaturated groups. Particularly preferred crosslinking monomers are the cyclic monomers triallyl cyanurate, triallyl isocyanurate, triacryloylhexahydro-s-triazine, triallylbenzenes. The amount of the crosslinking monomers is preferably 0.02 to 5, in particular 0.05 to 2 wt. %, based on the graft base B.2). In the case of cyclic crosslinking monomers having at least three ethylenically unsaturated groups, it is advantageous to limit the amount to less than 1 wt. % of the graft base B.2).

Preferred “other” polymerizable, ethylenically unsaturated monomers which can optionally serve for preparation of the graft base B.2 in addition to the acrylic acid esters are e.g. acrylonitrile, styrene, α-methylstyrene, acrylamides, vinyl C₁-C₆-alkyl ethers, methyl methacrylate, butadiene. Preferred acrylate rubbers as the graft base B.2) are emulsion polymers which have a gel content of at least 60 wt. %.

The silicone rubbers which are preferably employed as graft bases according to B.2) are those having grafting-active sites, such as are described in DE-OS 3 704 657, DE-OS 3 704 655, DE-OS 3 631 540 and DE-OS 3 631 539.

Composite rubbers of silicone rubber and acrylate rubber are particularly preferred as the graft bases B.2), these two rubber types being, for example, in the form of a physical mixture, or the silicon rubber and acrylate rubber, for example, forming an interpenetrating network as a result of the preparation, or, for example, the silicon rubber and acrylate rubber forming a graft base which has a core-shell structure. Preferred graft bases B.2) are composite rubbers of from 10 to 70 wt. %, particularly preferably 20 to 60 wt. % of silicone rubber and 90 to 30 wt. %, particularly preferably 80 to 40 wt. % of butyl acrylate rubber (the wt.% stated here is in each case based on the total weight of the graft base B.2)).

The silicone acrylate rubbers are preferably composite rubbers with grafting-active sites, the silicone rubber and acrylate rubber in the composite rubber penetrating each other, so that they cannot substantially be separated from one another.

Silicone/acrylate rubbers are known and are described, for example, in U.S. Pat. No. 5,807,914, EP 430134 and U.S. Pat. No. 4,888,388.

Preferably, silicone rubber components of the silicone/acrylate rubber according to B.2) are prepared by emulsion polymerization, in which the siloxane monomer units, crosslinking or branching agents and optionally grafting agents are employed.

Siloxane monomer units which are employed are, for example and preferably, dimethylsiloxane or cyclic organosiloxanes having at least 3 ring members, preferably 3 to 6 ring members, such as, for example and preferably, hexamethylcyclotrisiloxane, octamethylcyclotetrasiloxane, decamethylcyclopentasiloxane, dodecamethylcyclohexasiloxane, trimethyl-triphenyl-cyclotrisiloxanes, tetramethyl-tetraphenyl-cyclotetrasiloxanes, octaphenylcyclotetrasiloxane.

The organosiloxane monomers can be employed by themselves or in the form of mixtures with 2 or more monomers. The silicone rubber preferably contains not less than 50 wt. % and particularly preferably not less than 60 wt. % of organosiloxane, based on the total weight of the silicone rubber component.

Silane-based crosslinking agents having a functionality of 3 or 4, particularly preferably 4, are preferably used as crosslinking or branching agents. There may be mentioned by way of example and preferably: trimethoxymethylsilane, triethoxyphenylsilane, tetramethoxysilane, tetraethoxysilane, tetra-n-propoxysilane and tetrabutoxysilane. The crosslinking agent can be employed by itself or in a mixture of two or more. Tetraethoxysilane is particularly preferred.

The crosslinking agent is employed in a range of amounts of between 0.1 and 40 wt. %, based on the total weight of the silicone rubber component. The amount of crosslinking agent is chosen such that the degree of swelling of the silicone rubber, measured in toluene, is between 3 and 30, preferably between 3 and 25 and particularly preferably between 3 and 15. The degree of swelling is defined as the weight ratio between the amount of toluene which is absorbed by the silicone rubber when it is saturated with toluene at 25° C. and the amount of silicone rubber in the dried state. The determination of the degree of swelling is described in detail in EP 249964.

Tetrafunctional crosslinking agents are preferred over trifunctional, because the degree of swelling can then be controlled more easily within the limits described above.

Suitable grafting agents (IV) are compounds which are capable of forming structures of the following formulae:

CH₂═C(R⁸)-COO-(CH₂)ₚ-SiR⁷ₙO_{(3-n)/2} (IV-1)

CH₂═CH—SiR⁷ₙO_{(3-n)/2} (IV-2) or

HS-(CH₂)ₚ-SiR⁷ₙO(3-n)/2 (IV-3)

wherein

R⁷ represents C₁-C₄-alkyl, preferably methyl, ethyl or propyl, or phenyl,

R⁸ represents hydrogen or methyl,

n denotes 0, 1 or 2 and

p denotes an integer from 1 to 6.

Acryloyl- or methacryloyloxysilanes are particularly suitable for forming the abovementioned structure (IV-1) and have a high grafting efficiency. An effective formation of the graft chains is thereby ensured, and the impact strength of the resulting resin composition is therefore favoured.

There may be mentioned by way of example and preferably: β-methacryloyloxy-ethyldimethoxymethyl-silane, γ-methacryloyloxy-propylmethoxydimethyl-silane, γ-methacryloyloxy-propyldimethoxymethyl-silane, γ-methacryloyloxy-propyltrimethoxy-silane, γ-methacryloyloxy-propylethoxydiethyl-silane, γ-methacryloyloxy-propyldiethoxymethyl-silane, δ-methacryloyloxy-butyldiethoxymethyl-silanes or mixtures of these.

0 to 20 wt. % of grafting agent, based on the total weight of the silicone rubber, is preferably employed.

The silicone rubber can be prepared by emulsion polymerization, as described, for example, in U.S. Pat. No. 2,891,920 and U.S. Pat. No. 3,294,725. The silicone rubber is obtained by this means in the form of an aqueous latex. For this, a mixture containing organosiloxane, crosslinking agent and optionally grafting agent is mixed with water under the action of shearing forces, for example by a homogenizer, in the presence of an emulsifier based, in a preferred embodiment, on a sulfonic acid, such as e.g. alkylbenzenesulfonic acid or alkylsulfonic acid, the mixture polymerizing to give the silicone rubber latex. An alkylbenzenesulfonic acid is particularly suitable, since it acts not only as an emulsifier but also as a polymerization initiator. In this case, a combination of the sulfonic acid with a metal salt of an alkylbenzenesulfonic acid or with a metal salt of an alkylsulfonic acid is favourable, because the polymer is thereby stabilized during the later grafting polymerization.

After the polymerization, the reaction is ended by neutralizing the reaction mixture by addition of an aqueous alkaline solution, e.g. by addition of an aqueous sodium hydroxide, potassium hydroxide or sodium carbonate solution.

Suitable polyalkyl (meth)acrylate rubber components of the silicone/acrylate rubbers according to B.2) can be prepared from methacrylic acid alkyl esters and/or acrylic acid alkyl esters, a crosslinking agent and a grafting agent. Methacrylic acid alkyl esters and/or acrylic acid alkyl esters which are by way of example and preferred here are the C, to C₈-alkyl esters, for example methyl, ethyl, n-butyl, t-butyl, n-propyl, n-hexyl n-octyl, n-lauryl and 2-ethylhexyl esters; haloalkyl esters, preferably halo-C₁-C₈-alkyl esters, such as chloroethyl acrylate, and mixtures of these monomers. n-Butyl acrylate is particularly preferred.

Crosslinking agents which can be employed for the polyalkyl (meth)acrylate rubber component of the silicone/acrylate rubber are monomers having more than one polymerizable double bond. Preferred examples of crosslinking monomers are esters of unsaturated monocarboxylic acids having 3 to 8 C atoms and unsaturated monofunctional alcohols having 3 to 12 C atoms, or of saturated polyols having 2 to 4 OH groups and 2 to 20 C atoms, such as ethylene glycol dimethacrylate propylene glycol dimethacrylate, 1,3-butylene glycol dimethacrylate and 1,4-butylene glycol dimethacrylate. The crosslinking agents can be used by themselves or in mixtures of at least two crosslinking agents.

Grafting agents which are by way of example and preferred are allyl methacrylate, triallyl cyanurate, triallyl isocyanurate or mixtures of these. Allyl methacrylate can also be employed as the crosslinking agent. The grafting agents can be used by themselves or in mixtures of at least two grafting agents.

The amount of crosslinking agent and grafting agent is 0.1 to 20 wt. %, based on the total weight of the polyalkyl (meth)acrylate rubber component of the silicone/acrylate rubber.

The silicone/acrylate rubber is prepared by first preparing the silicone rubber as an aqueous latex. This latex is then enriched with the methacrylic acid alkyl esters and/or acrylic acid alkyl esters to be used, the crosslinking agent and the grafting agent, and a polymerization is carried out. An emulsion polymerization initiated by free radicals, for example by a peroxide initiator or an azo or redox initiator, is preferred. The use of a redox initiator system, specifically of a sulfoxylate initiator system prepared by combination of iron sulfate, disodium ethylenediaminetetraacetate, Rongalit and hydroperoxide, is particularly preferred.

The grafting agent used in the preparation of the silicone rubber leads in this context to the polyalkyl (meth)acrylate rubber content being bonded covalently to the silicone rubber content. During the polymerization, the two rubber components penetrate each other and in this way form the composite rubber, which can no longer be separated into its constituents of silicone rubber component and polyalkyl (meth)acrylate rubber component after the polymerization.

### Component C)

The rubber-free vinyl (co)polymers according to component C) are preferably rubber-free homo- and/or copolymers of at least one monomer from the group of vinylaromatics, vinyl cyanides (unsaturated nitriles), (meth)acrylic acid (C₁ to C₈)-alkyl esters, unsaturated carboxylic acids and derivatives (such as anhydrides and imides) of unsaturated carboxylic acids.

(Co)polymers C) which are suitable in particular are those of
C.1) 50 to 99 wt. %, preferably 60 to 80 wt. %, in particular 70 to 80 wt.%, in each case based on the total weight of (co)polymer C), of at least one monomer chosen from the group of vinylaromatics, such as, for example, styrene, α-methylstyrene, vinylaromatics substituted on the nucleus, such as, for example, p-methylstyrene, p-chlorostyrene, and (meth)acrylic acid (C₁-C₈)-alkyl esters, such as, for example, methyl methacrylate, n-butyl acrylate, tert-butyl acrylate, and
C.2) 1 to 50 wt. %, preferably 20 to 40 wt. %, in particular 20 to 30 wt.%, in each case based on the total weight of (co)polymer C), of at least one monomer chosen from the group of vinyl cyanides, such as, for example, unsaturated nitriles, such as e.g. acrylonitrile and methacrylonitrile, (meth)acrylic acid (C₁-C₈)-alkyl esters, such as, for example, methyl methacrylate, n-butyl acrylate, tert-butyl acrylate, unsaturated carboxylic acids and derivatives of unsaturated carboxylic acids, such as, for example, maleic anhydride and N-phenyl-maleimide.

These (co)polymers C) are resinous, thermoplastic and rubber-free. The copolymer of

C.1) styrene and C.2) acrylonitrile is particularly preferred.

Such (co)polymers C) are known and can be prepared by free-radical polymerization, in particular by emulsion, suspension, solution or bulk polymerization. The (co)polymers preferably have average molecular weights M_{W} (weight-average, determined by GPC) of between 15,000 and 250,000 g/mol, preferably in the range of 80,000 to 150,000 g/mol.

Possible aromatic polyesters are, preferably, polyalkylene terephthalates. Polyalkylene terephthalates are reaction products of aromatic dicarboxylic acids or their reactive derivatives, such as dimethyl esters or anhydrides, and aliphatic, cycloaliphatic or araliphatic diols, and mixtures of these reaction products.

Preferred polyalkylene terephthalates contain at least 80 wt. %, preferably at least 90 wt. %, based on the dicarboxylic acid component, of terephthalic acid radicals and at least 80 wt. %, preferably at least 90 mol %, based on the diol component, of radicals of ethylene glycol and/or butane-1,4-diol.

The preferred polyalkylene terephthalates can contain, in addition to terephthalic acid radicals, up to 20 mol %, preferably up to 10 mol % of radicals of other aromatic or cycloaliphatic dicarboxylic acids having 8 to 14 C atoms or aliphatic dicarboxylic acids having 4 to 12 C atoms, such as e.g. radicals of phthalic acid, isophthalic acid, naphthalene-2,6-dicarboxylic acid, 4,4′-diphenyldicarboxylic acid, succinic acid, adipic acid, sebacic acid, azelaic acid and cyclohexanediacetic acid.

The preferred polyalkylene terephthalates can contain, in addition to radicals of ethylene glycol or butane-1,4-diol, up to 20 mol %, preferably up to 10 mol % of other aliphatic diols having 3 to 12 C atoms or cycloaliphatic diols having 6 to 21 C atoms, e.g. radicals of propane-1,3-diol, 2-ethylpropane-1,3-diol, neopentyl glycol, pentane-1,5-diol, hexane-1,6-diol, cyclohexane-1,4-dimethanol, 3-ethylpentane-2,4-diol, 2-methylpentane-2,4-diol, 2,2,4-trimethylpentane-1,3-diol, 2-ethylhexane-1,3-diol, 2,2-diethylpropane-1,3-diol, hexane-2,5-diol, 1,4-di-(β-hydroxyethoxy)-benzene, 2,2-bis-(4-hydroxycyclohexyl)-propane, 2,4-dihydroxy-1,1,3,3-tetramethylcyclobutane, 2,2-bis-(4-β-hydroxyethoxyphenyl)-propane and 2,2-bis-(4-hydroxypropoxyphenyl)-propane (DE-A 2 407 674, 2 407 776, 2 715 932).

The polyalkylene terephthalates can be branched by incorporation of relatively small amounts of 3- or 4-functional alcohols or 3- or 4-basic carboxylic acids, e.g. in accordance with DE-A 1 900 270 and U.S. Pat. No. 3 692 744. Examples of preferred branching agents are trimesic acid, trimellitic acid, trimethylolethane and -propane and pentaerythritol.

Polyalkylene terephthalates which have been prepared solely from terephthalic acid and reactive derivatives thereof (e.g. dialkyl esters thereof) and ethylene glycol and/or butane-1,4-diol, and mixtures of these polyalkylene terephthalates are particularly preferred.

Mixtures of polyalkylene terephthalates contain 1 to 50 wt. %, preferably 1 to 30 wt. % of polyethylene terephthalate and 50 to 99 wt. %, preferably 70 to 99 wt. % of polybutylene terephthalate.

The polyalkylene terephthalates preferably used in general have a limiting viscosity of from 0.4 to 1.5 dl/g, preferably 0.5 to 1.2 dl/g, measured in phenol/o-dichlorobenzene (1:1 parts by weight) at 25° C. in an Ubbelohde viscometer.

The polyalkylene terephthalates can be prepared by known methods (see e.g. Kunststoff-Handbuch, volume VIII, p. 695 et seq., Carl-Hanser-Verlag, Munich 1973).

### Component D)

The composition can optionally comprise commercially available polymer additives as component D). Possible commercially available polymer additives according to component D) are additives such as, for example, flameproofing agents (for example phosphorus compounds or halogen compounds), flameproofing synergists (for example nanoscale metal oxides), smoke-suppressing additives (for example boric acid or borates), antidripping agents (for example compounds from the substance classes of fluorinated polyolefins, of silicones and aramid fibres), internal and external lubricants and mould release agents (for example pentaerythritol tetrastearate, montan wax or polyethylene wax), flowability auxiliary agents (for example low molecular weight vinyl (co)polymers), antistatics (for example block copolymers of ethylene oxide and propylene oxide, other polyethers or polyhydroxy ethers, polyether amides, polyester amides or sulfonic acid salts), conductivity additives (for example conductive carbon black or carbon nanotubes), stabilizers (for example UV/light stabilizers, heat stabilizers, antioxidants, transesterification inhibitors, agents which prevent hydrolysis), antibacterially acting additives (for example silver or silver salts), additives which improve scratch resistance (for example silicone oils or hard fillers, such as ceramic (hollow) spheres), IR absorbents, optical brighteners, fluorescent additives, fillers and reinforcing substances (for example talc, optionally ground glass or carbon fibres, glass or ceramic (hollow) spheres, mica, kaolin, CaCO₃ and glass flakes) and dyestuffs and pigments (for example carbon black, titanium dioxide or iron oxide), and Bronsted acid compounds as base scavengers, or mixtures of several of the additives mentioned.

Preferably, the composition comprises at least one polymer additive chosen from the group of lubricants and mould release agents, heat stabilizers and pigments.

Possible pigments are, preferably, white or black pigments. In preferred embodiments, the composition comprises at least one white pigment. Suitable white pigments are, for example, titanium dioxide, zinc sulfide, zirconium dioxide or barium sulfate, titanium dioxide being preferred. In preferred embodiments, the composition comprises the pigment or pigments in an amount of from 0.5 to 20 parts by wt., preferably 1 to 15 parts by wt., particularly preferably 2 to 10 parts by wt., based on the sum of components A)+B)+C).

In further preferred embodiments of the invention, the composition comprises no pigment. Embodiments without pigments are translucent films.

In further preferred embodiments of the invention, the composition comprises no mould release agent.

In further preferred embodiments of the invention, the composition comprises as component D) at least one phosphorus-containing compound as a flameproofing agent. This is/these are preferably chosen from the groups of mono- and oligomeric phosphoric and phosphonic acid esters, phosphonatamines and phosphazenes, it also being possible to employ mixtures of several components chosen from one or various of these groups as the flameproofing agent. Other preferably halogen-free phosphorus compounds not mentioned specifically here can also be employed by themselves or in any desired combination with other preferably halogen-free phosphorus compounds.

Preferred mono- or oligomeric phosphoric or phosphonic acid esters are phosphorus compounds of the general formula (V)

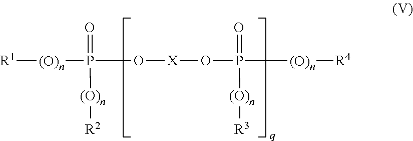

wherein
R¹, R², R³ and R⁴ independently of each other denote in each case Optionally halogenated C₁ to C₈-alkyl, or C₅ to C₆-cycloalkyl, C₆ to C₂₀-aryl or C₇ to C₁₂-aralkyl in each case optionally substituted by alkyl, preferably C₁ to Cₐ-alkyl, and/or halogen, preferably chlorine, bromine,
n independently of each other denote 0 or 1,
q denotes 0 to 30 and
X denotes a mono- or polynuclear aromatic radical having 6 to 30 C atoms, or a linear or branched aliphatic radical having 2 to 30 C atoms, which can be substituted by OH and can contain up to 8 ether bonds.

Preferably, R¹, R², R³ and R⁴ independently of each other represent C₁ to C₄-alkyl, phenyl, naphthyl or phenyl-C₁-C₄-alkyl. The aromatic groups R¹, R², R³ and R⁴ can in their turn be substituted by halogen groups and/or alkyl groups, preferably chorine, bromine and/or C₁ to C₄-alkyl. Particularly preferred aryl radicals are cresyl, phenyl, xylenyl, propylphenyl or butylphenyl and the corresponding brominated and chlorinated derivatives thereof.
X in the formula (V) preferably denotes a mono- or polynuclear aromatic radical having 6 to 30 C atoms. This is preferably derived from diphenols of the formula (I).
n in the formula (V) can be, independently of each other, 0 or 1, and preferably n is 1.
q represents values from 0 to 30, preferably 0.3 to 20, particularly preferably 0.5 to 10, in particular 0.5 to 6, very particularly preferably 1.1 to 1.6.
X particularly preferably represents

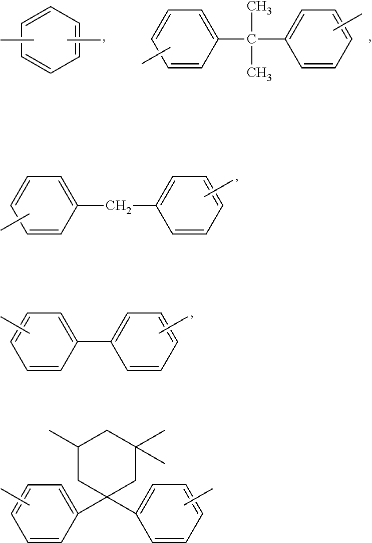

or chlorinated or brominated derivatives thereof, and in particular X is derived from resorcinol, hydroquinone, bisphenol A or diphenylphenol. Particularly preferably, X is derived from bisphenol A.

Mixtures of various phosphates can also be employed in or as component D).

Phosphorus compounds of the formula (V) are, in particular, tributyl phosphate, triphenyl phosphate, tricresyl phosphate, diphenyl cresyl phosphate, diphenyl octyl phosphate, diphenyl 2-ethylcresyl phosphate, tri-(isopropylphenyl) phosphate, resorcinol-bridged oligophosphate and bisphenol A-bridged oligophosphate. The use of oligomeric phosphoric acid esters of the formula (V) which are derived from bisphenol A is particularly preferred.

A very particularly preferred phosphorus compound of the formula (V) is the bisphenol

A-based oligophosphate according to formula (Va)

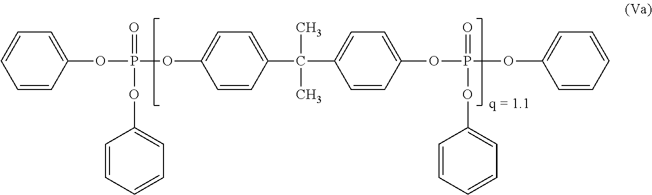

The abovementioned phosphorus compounds are known (cf. e.g. EP-A 0 363 608, EP-A 0 640 655) or can be prepared by known methods in an analogous manner (e.g. Ullmanns Enzyklopädie der technischen Chemie, vol. 18, p. 301 et seq. 1979; Houben-Weyl, Methoden der organischen Chemie, vol. 12/1, p. 43; Beilstein vol. 6, p. 177).

If mixtures of various phosphorus compounds are employed, and in the case of oligomeric phosphorus compounds, the q value stated is the average q value. The average q value can be determined by determining the composition of the phosphorus compound (molecular weight distribution) by means of a suitable method (gas chromatography (GC), high pressure liquid chromatography (HPLC), gel permeation chromatography (GPC)) and calculating the mean values for q therefrom.

Phosphonatamines and phosphazenes such as are described in WO-A 00/00541 and WO-A 01/18105 can furthermore be employed as flameproofing agents.

The flameproofing agents can be employed by themselves or in any desired mixture with one another or in a mixture with other flameproofing agents or other additives.

In a preferred embodiment, the flameproofing agents are employed in combination with polytetrafluoroethylene (PTFE) as an antidripping agent.

The compositions suitable for the rear face film of the solar modules according to the invention are prepared by mixing the particular constituents in a known manner and subjecting the mixture to melt compounding and melt extrusion at temperatures of from 200° C. to 300° C. in conventional units, such as internal kneaders, extruders and twin-screw extruders. The mixing of the individual constituents can be carried out in a known manner either successively or simultaneously, and in particular either at about 20° C. (room temperature) or at a higher temperature.

The single- or multilayer film on the rear face of the solar module according to the invention preferably has a thickness of from 100 to 500 μm, particularly preferably from 200 to 400 μm.

In preferred embodiments, the film on the rear face is a single-layer film.

In further preferred embodiments, the film on the rear face is a multilayer film which comprises at least one layer based on a thermoplastic with a water vapour diffusion of less than 3 g/m²·d at 38° C., measured in accordance with ISO 15106-1, and a glass transition temperature of from 60 to 100° C., measured by means of dynamic differential thermal analysis (DSC) in accordance with one of the standards DIN EN ISO 11357, DIN 53765 or DIN EN 61006. In particularly preferred embodiments, the film on the rear face is a multilayer film which comprises at least one layer based on a thermoplastic with a water vapour diffusion of less than 3 g/m²·d and a glass transition temperature of from 60 to 100° C. between at least two layers of a composition comprising the components
A) 30 to 85 parts by wt., based on the sum of components A)+B)+C), of aromatic polycarbonate and/or aromatic polyester carbonate,
B) 7 to 70 parts by wt., based on the sum of components A)+B)+C), of a rubber-containing graft polymer,
C) 0 to 60 parts by wt., based on the sum of components A)+B)+C), of a rubber-free vinyl monomer-based polymer or vinyl monomer-based copolymer or alternatively of an aromatic polyester, the sum of components A to C being standardized to 100 parts by wt., and optionally
D) 0 to 30 parts by wt., based on the sum of components A)+B)+C), of at least one commercially available polymer additive.

The abovementioned preferred ranges for the individual components of the composition apply equally for this.

Preferably, the film on the rear face of the solar module comprises a layer based on a thermoplastic with a water vapour diffusion of less than 3 g/m²·d and a glass transition temperature of from 60 to 100° C. between two layers of the abovementioned composition.

Possible plastics with a water vapour diffusion of less than 3 g/m²·d and a glass transition temperature of from 60 to 100° C. are, for example, those based on poly- or copolycondensates of terephthalic acid, such as, for example, poly- or copolyethylene terephthalate (PET or CoPET), glycol-modified PET (PETG), glycol-modified poly- or copolycyclohexanedimethylene terephthalate (PCTG) or poly- or copolybutylene terephthalate (PBT or CoPBT).

The film on the rear face of the solar module can be an extruded or coextruded film. Multilayer films for the rear face of the solar module are preferably coextruded films. Such films are obtainable in only a single extrusion step, which, for example, saves additional outlay for the stepwise application of several layers.

It is moreover advantageous that the rear face films described above have an additional adhesion promoter coating in order to improve the adhesion to the embedding material for the solar cell(s). Such an adhesion promoter coating either can be produced directly on the film by means of coextrusion, or it can be applied subsequently by means of extrusion lamination or wet chemistry methods, such as e.g. knife coating, spraying, pouring, roller application, application through an extruder die etc. Suitable adhesion promoters in this context are, for example, polyurethanes, for example employed as polyurethane dispersions, adhesion promoters based on polymethyl methacrylate (PMMA) or other coatings which have a good adhesion to the conventional embedding materials, such as e.g. thermoplastic polyurethane or ethylene/vinyl acetate.

The rear face films used according to the invention offer the solar modules according to the invention an excellent protection against weathering (in particular resistance in a damp warm climate) and mechanical damage. The solar modules according to the invention correspondingly show excellent resistance to weathering and stability to hydrolysis with good protection against mechanical damage.

The use of such films as a rear face film in solar modules has not hitherto been known. The present invention therefore furthermore provides such a use of a single- or multilayer film comprising at least one layer of a composition comprising at least the following components
A) 30 to 85 parts by wt., based on the sum of components A)+B)+C), of aromatic polycarbonate and/or aromatic polyester carbonate,
B) 7 to 70 parts by wt., based on the sum of components A)+B)+C), of a rubber-containing graft polymer,
C) 0 to 60 parts by wt., based on the sum of components A)+B)+C), of a rubber-free vinyl monomer-based polymer or vinyl monomer-based copolymer or alternatively of an aromatic polyester,
   the sum of components A to C being standardized to 100 parts by wt., and optionally
D) 0 to 30 parts by wt., based on the sum of components A)+B)+C), of at least one commercially available polymer additive.

The abovementioned preferred ranges for the film and the individual components of the composition apply equally for this.

The solar module according to the invention can be produced in a simple manner, for example by first stacking the individual layers and then laminating them. This can be carried out in a single laminating step or in several successive laminating steps.

The present invention therefore furthermore provides a process for the production of a solar module according to the invention, characterized in that a layer arrangement of
a) at least one transparent glass pane, sheet of plastic or film of plastic for the front face
b) at least one film of a transparent plastic
c) solar cells
d) at least one further film of a transparent plastic according to b)
e) at least one single- or multilayer film for the rear face is produced and then laminated.

In this context, the two films of a transparent plastic according to b) and d) form, by the lamination, the embedding layer(s) for the solar cell(s) between the transparent glass pane, sheet of plastic or film of plastic and the single- or multilayer rear face film. The films according to b) and d) are therefore preferably hot-melt adhesive films.

The following examples serve to explain the invention by way of example and are not to be interpreted as a limitation.

### EXAMPLES

### Polvcarbonate Compositions

### Component A

Linear polycarbonate based on bisphenol A having a weight-average molecular weight M_{w} of 32,000 g/mol (determined by GPC in methylene chloride).

### Component B

Metablen® SRK200 (Mitsubishi Rayon Co., Ltd., Tokyo, Japan): graft polymer comprising a shell of styrene/acrylonitrile copolymer on a particulate core of silicone/butyl acrylate composite rubber, prepared by emulsion polymerization.

### Component C

Styrene/acrylonitrile copolymer (SAN) with a styrene/acrylonitrile weight ratio of 76:24 and an average molecular weight M_{w} of 100,000 g/mol (determined by GPC in dimethylformamide).

### Component D

D1: Pentaerythritol tetrastearke (PETS) as a lubricant/mould release agent

D2: Irganox® B900 (Ciba Specialty Chemicals, Basle, Switzerland) as a heat stabilizer

D3: Talc as a reinforcing substance

D4: Titanium dioxide as a pigment

TABLE 1
Polycarbonate compositions used for the production of the rear
face films to be employed (stated in parts by weight)

| | Example | | | | | |
|---|---|---|---|---|---|---|
| Composition | 1 | 2 | 3 | 3a | 4 | 7 |
| Component A (polycarbonate) | 95 | 90 | 60 | 60 | 80 | 90 |
| Component B (Metablen ® | 5 | 5 | 20 | 20 | 10 | |
| SRK200) | | | | | | |
| Component C (SAN) | — | 5 | 20 | 20 | 10 | |
| Component D1 (PETS) | 0.5 | 0.5 | 0.5 | | 0.5 | |
| Component D2 (Irganox ® | 0.1 | 0.1 | 0.1 | 0.1 | 0.1 | |
| B900) | | | | | | |
| Component D3 (talc) | — | — | — | — | 10 | |
| Component D4 (TiO₂) | 7 | 7 | 7 | 7 | 7 | 10 |

### Production of the rear face films

The rear face films to be employed were extruded in a thickness of 350 μm from granules with the particular compositions from Tab. 1.

### Example 1 (Comparison Example)

A film was produced from composition 1 from Tab. 1 by means of extrusion.

### Example 2 (Comparison Example)

A film was produced from composition 2 from Tab. 1 by means of extrusion.

### Example 3 (According to the Invention)

A film was produced from composition 3 from Tab. 1 by means of extrusion.

### Example 3a (According to the Invention)

A film was produced from composition 3a from Tab. 1 by means of extrusion.

### Example 4 (According to the Invention)

A film was produced from composition 4 from Tab. 1 by means of extrusion.

### Example 5 (According to the Invention)

A film was produced from composition 3 from Tab. 1 by means of extrusion and adhesion promoter (Tedlar® Adhesive 68040 from DuPont) was knife-coated in undiluted form on to the film and dried at 120° C.

### Example 6 (According to the Invention)

A multilayer film with a layer of glycol-modified polyethylene terephthalate (PETG) (Eastar™ DN001 from Eastman) between two layers of composition 3 from Tab. 1 was produced by means of coextrusion, the thickness of the layers of composition 3 in each case being 50 μm and that of the PETG layer being 250 μm.

### Example 7 (Comparison Example)

A film was produced from composition 7 from Tab. 1 by means of extrusion.

### Example 8 (Comparison Example)

A film was produced from composition 7 from Tab. 1 by means of extrusion and then coated with a 50 nm thick SiOₓ coating. The coating operation was carried out by electron beam vapour deposition of SiO in a vacuum chamber with an oxygen background pressure.

### Production and Testing of the Solar Modules

### Production of the Solar Modules

For production of the solar modules, first an ethylene/vinyl acetate film (EVA film)

(Vistasolar® 486.00 from Etimex®), on this a crystalline silicon solar cell, on this a further EVA film and finally the rear face film according to one of Examples 1-8 were laid on a 4 mm thick glass pane. This stack was then placed in a vacuum laminator LM 50×50 from NPC. The solar module was laminated in the vacuum laminator at 140° in the course of 26 minutes.

### Testing of the Solar Modules

The solar modules were subjected to weathering in the damp heat test (storage in damp heat for 1,000 h at 85° C. and 85% relative atmospheric humidity) in accordance with DIN EN 61730-2. The damp heat test was extended to 2,000 h in order to test the long-term suitability of the films. The solar modules were taken out of the test and evaluated after 500 h, 1,000 h and 2,000 h. The two most important criteria were: any cracking in the rear face film (due to embrittlement of the film) and delamination (especially in the edge region).

TABLE 2
Behaviour of the various solar modules in the damp heat test

| | Evaluation in the | | Evaluation in the | | Evaluation in the | |
|---|---|---|---|---|---|---|
| | damp heat test | | damp heat test | | damp heat test | |
| | After 500 h | | After 1,000 h | | After 2,000 h | |
| Example 1 (C) | Ed: − | Cr: ∘ | Ed: − | Cr: ∘ | not measured | |
| Example 2 (C) | Ed: − | Cr: ∘ | Ed: − | Cr: ∘ | not measured | |
| Example 3 (I) | Ed: ++ | Cr: ++ | Ed: ++ | Cr: ++ | Ed: ++ | Cr: ++ |
| Example 3a (I) | Ed: ++ | Cr: ++ | Ed: ++ | Cr: ++ | Ed: ++ | Cr: ++ |
| Example 4 (I) | Ed: + | Cr: + | Ed: ∘ | Cr: ∘ | Ed: ∘ | Cr: ∘ |
| Example 5 (I) | Ed: ++ | Cr: ++ | Ed: ++ | Cr: ++ | Ed: ++ | Cr: ++ |
| Example 6 (I) | Ed: + | Cr: ++ | still being tested | | still being tested | |
| Example 7 (C) | Ed: − | Cr: − | Ed: − | Cr: − | Ed: − | Cr: − |
| Example 8 (C) | Ed: − | Cr: − | Ed: − | Cr: − | Ed: − | Cr: − |

(C): Comparison example; (I): Example according to the invention; Ed: Edge delamination; Cr: Cracks;
++ very good; + good; ∘ acceptable; − poor

The data in Tab. 2 show that only those solar modules based on the rear face films according to the invention show a good to very good behaviour in the damp heat test (damp heat ageing test) and therefore a very good resistance to weathering. Furthermore, the solar modules based on the rear face films according to the invention showed very good protection against mechanical damage on the basis of the absence of cracking.

1-15. (canceled)

16. A solar module comprising
at least one transparent glass pane, sheet of plastic or film of plastic on the front face
at least one single- or multilayer film on the rear face
one or more solar cells
at least one layer of at least one transparent plastic, in which the solar cells are embedded, between the transparent glass pane, sheet of plastic or film of plastic and the single- or multilayer rear face film,
wherein the single- or multilayer film on the rear face has at least one layer of a composition comprising at least the following components:
A) 30 to 85 parts by wt., based on the sum of components A)+B)+C), of aromatic polycarbonate and/or aromatic polyester carbonate,
B) 7 to 70 parts by wt., based on the sum of components A)+B)+C), of a rubber-containing graft polymer,
C) 0 to 60 parts by wt., based on the sum of components A)+B)+C), of a rubber-free vinyl monomer-based polymer or vinyl monomer-based copolymer or of an aromatic polyester,
the sum of components A to C being standardized to 100 parts by wt., and optionally
D) 0 to 30 parts by wt., based on the sum of components A)+B)+C), of at least one polymer additive.

17. The solar module of claim 16, wherein the film on the rear face is a single- or multilayer film with a thickness of from 100 to 500 μm.

18. The solar module of claim 16, wherein the film on the rear face is a multilayer film which comprises at least one layer based on a thermoplastic with a water vapour diffusion of less than 3 g/m2·d and a glass transition temperature of from 60 to 100 ° C.

19. The solar module of claim 16, wherein the film on the rear face is a multilayer film which comprises at least one layer based on a thermoplastic with a water vapour diffusion of less than 3 g/m2·d and a glass transition temperature of from 60 to 100 ° C. between at least two layers of a composition comprising the components
A) 30 to 85 parts by wt., based on the sum of components A)+B)+C), of aromatic polycarbonate and/or aromatic polyester carbonate,
B) 7 to 70 parts by wt., based on the sum of components A)+B)+C), of a rubber-containing graft polymer,
C) 0 to 60 parts by wt., based on the sum of components A)+B)+C), of a rubber-free vinyl monomer-based polymer or copolymer or of an aromatic polyester, the sum of components A to C being standardized to 100 parts by wt., and optionally
D) 0 to 30 parts by wt., based on the sum of components A)+B)+C), of at least one commercially available polymer additive.

20. The solar module of claim 16, wherein the composition comprises component C) to the extent of 5 to 40 parts by wt., based on the sum of components A+B+C.

21. The solar module of claim 16, wherein component A) in the composition is an aromatic polycarbonate and/or aromatic polyester carbonate based on 2,2-bis-(4-hydroxyphenyl)-propane (bisphenol A).

22. The solar module of claim 16, wherein component B) in the composition is a graft polymer based on a diene-free rubber, preferably based on an acrylate rubber and/or silicone rubber, very particularly preferably based on a silicone/acrylate composite rubber.

23. The solar module of claim 16, wherein component B) in the composition includes the following components
B.1) 5 to 95 wt. %, preferably 20 to 90 wt. %, particularly preferably 25 to 50 wt. %, based on the total weight of component B), of at least one vinyl monomer, and
B.2) 95 to 5 wt. %, preferably 80 to 10 wt. %, particularly preferably 75 to 50 wt. %, based on the total weight of component B), of one or more graft bases with glass transition temperatures<10° C., preferably<0° C., particularly preferably<−20° C.
the parts by weight of components B.1) and B.2) adding up to 100 wt. %.

24. The solar module of claim 23, wherein component B.1) in the composition is a mixture of the following monomers
B.1.1) 50 to 99 wt. %, preferably 60 to 80 wt. %, particularly preferably 70 to 80 wt.%, based on the total weight of component B.1), of vinylaromatics and/or vinylaromatics substituted on the nucleus and/or methacrylic acid (C₁-C₈)-alkyl esters and
B.1.2) 1 to 50 wt. %, preferably 20 to 40 wt. %, in particular 20 to 30 wt.%, based on the total weight of component B.1), of vinyl cyanides and/or (meth)acrylic acid (C₁-C₈)-alkyl esters and/or derivatives of unsaturated carboxylic acids,
the parts by weight of components B.1.1) and B.1.2) adding up to 100 wt. %.

25. The solar module of claim 16, wherein component C) in the composition is a polymer or copolymer of one or more monomer(s) chosen from the group of vinylaromatics, vinylaromatics substituted on the nucleus, vinyl cyanides, (meth)acrylic acid (C1-C8) alkyl esters, unsaturated carboxylic acids and derivatives of unsaturated carboxylic acids.

26. The solar module of claim 16, wherein the composition comprises component D) to the extent of 0.01 to 20 parts by wt., based on the sum of components A)+B)+C).

27. The solar module of claim 16, wherein component D) in the composition is at least one polymer additive chosen from the group of lubricants and mould release agents, heat stabilizers and pigments.

28. The solar module of claim 16, wherein component D) in the composition includes at least one white pigment, preferably titanium dioxide, which the composition comprises in an amount of from 0.5 to 20 parts by wt., preferably 1 to 15 parts by wt., particularly preferably 2 to 10 parts by wt., based on the sum of components A)+B)+C).

29. A process for producing the solar module of claim 16, wherein a layer arrangement of
a) at least one transparent glass pane, sheet of plastic or film of plastic for the front face
b) at least one film of a transparent plastic
c) solar cells
d) at least one further film of a transparent plastic according to b)
e) at least one single- or multilayer film for the rear face is produced and then laminated.

30. Use of a single- or multilayer film comprising at least one layer of a composition comprising at least the following components:
A) 30 to 85 parts by wt., based on the sum of components A)+B)+C), of aromatic polycarbonate and/or aromatic polyester carbonate,
B) 7 to 70 parts by wt., based on the sum of components A)+B)+C), of a rubber-containing graft polymer,
C) 0 to 60 parts by wt., based on the sum of components A)+B)+C), of a rubber-free vinyl monomer-based polymer or vinyl monomer-based copolymer or of an aromatic polyester,
the sum of components A to C being standardized to 100 parts by wt., and optionally D) 0 to 30 parts by wt., based on the sum of components A)+B)+C), of at least one commercially available polymer additive.
as a rear face film in solar modules.
